(19) United States
(12) Patent Application Publication
(10) Pub. No.: US 2025/0301891 A1
(43) Pub. Date: Sep. 25, 2025

(54) LIGHT EMITTING DEVICE, DISPLAY DEVICE, PHOTOELECTRIC CONVERSION DEVICE, AND ELECTRONIC APPARATUS

(71) Applicant: CANON KABUSHIKI KAISHA, Tokyo (JP)

(72) Inventor: SATOSHI INAI, Kanagawa (JP)

(21) Appl. No.: 19/078,379

(22) Filed: Mar. 13, 2025

(30) Foreign Application Priority Data
Mar. 25, 2024 (JP) 2024-048568

(51) Int. Cl. H10K 59/80; H10K 59/122

(52) U.S. Cl. CPC H10K 59/878; H10K 59/122

(57) ABSTRACT

A light emitting device including a light emitting element is provided. The light emitting element includes an electrode, a bank arranged to cover an edge of the electrode and provided with an opening configured to expose the electrode, and an organic layer including a light emitting layer and connected to the electrode in the opening. A side surface of the bank facing the opening includes a first surface formed by a first portion made of a first material, and a second surface arranged between the first surface and the electrode and formed by a second portion made of a second material, the first portion reflects more light emitted by the light emitting layer than the second portion, and the second portion has insulating property, and absorbs more light emitted by the light emitting layer than the first portion.

### BACKGROUND OF THE INVENTION

### Field of the Invention

The present disclosure relates to a light emitting device, a display device, a photoelectric conversion device, and an electronic apparatus.

### Description of the Related Art

There is known a light emitting device that includes a light emitting element using an organic electroluminescence (EL) element. The light emitting element can be isolated for each pixel by a bank using an insulating material or the like, and each pixel can independently be driven to emit light. In such a light emitting device, if light emission crosstalk occurs, which is caused by light emitted from one pixel and entering an adjacent pixel, display image quality may be deteriorated. US-2019-0027547 describes that, in order to suppress light emission crosstalk between pixels, a light blocking layer for absorbing light is provided to cover the upper and side surfaces of the bank.

### SUMMARY OF THE INVENTION

The structure described in US-2019-0027547 can suppress light emission crosstalk. On the other hand, the light blocking layer may absorb the light which is emitted from a light emitting layer and reflected by the bank in a light extraction direction if the light blocking layer is not provided. In this case, light extraction efficiency can be deteriorated.

Some embodiments of the present disclosure provide a technique advantageous in achieving both suppressing light emission crosstalk and improving light extraction efficiency.

According to some embodiments, a light emitting device that comprises a light emitting element including a first electrode arranged on a main surface of a substrate, a bank arranged to cover an outer edge of the first electrode and provided with an opening portion configured to expose the first electrode inside the outer edge, an organic layer arranged on the first electrode, and a second electrode arranged to cover the organic layer, wherein the organic layer includes a light emitting layer and connected to the first electrode in the opening portion, a side surface of the bank facing the opening portion includes a first surface formed by a first portion made of a first material, and a second surface arranged between the first surface and the first electrode and formed by a second portion made of a second material different from the first material, the first portion reflects more light emitted by the light emitting layer than the second portion, and the second portion has insulating property, and absorbs more light emitted by the light emitting layer than the first portion, is provided.

Further features of the present invention will become apparent from the following description of exemplary embodiments (with reference to the attached drawings).

### BRIEF DESCRIPTION OF THE DRAWINGS

FIG. 1 is a sectional view showing an example of the arrangement of light emitting elements arranged in a light emitting device according to an embodiment;

FIG. 2 is a plan view showing an example of the arrangement of the light emitting elements shown in FIG. 1;

FIG. 3 is an enlarged view of the light emitting element shown in FIG. 1;

FIGS. 4A and 4B are views for explaining the effect of the light emitting element shown in FIG. 1;

FIGS. 5A to 5D are views for explaining the effect of the light emitting element shown in FIG. 1;

FIGS. 6A to 6C are views showing an example of the manufacturing step of the light emitting element shown in FIG. 1;

FIGS. 7A to 7C are views showing the example of the manufacturing step of the light emitting element shown in FIG. 1;

FIGS. 8A to 8C are views showing the example of the manufacturing step of the light emitting element shown in FIG. 1;

FIGS. 9A to 9C are views showing a modification of the light emitting element shown in FIG. 1 and an example of the manufacturing step thereof;

FIGS. 10A to 10C are views showing a modification of the light emitting element shown in FIG. 1 and an example of the manufacturing step thereof;

FIGS. 11A to 11E are views showing a modification of the light emitting element shown in FIG. 1 and an example of the manufacturing step thereof;

FIG. 12 is a view showing a modification of the light emitting element shown in FIG. 1;

FIGS. 13A and 13B are sectional views showing an example of the arrangement of the pixel of the light emitting device shown in FIG. 1;

FIGS. 14A to 14C are views showing an example of an image forming device using the light emitting device according to the embodiment;

FIG. 15 is a view showing an example of a display device using the light emitting device according to the embodiment;

FIG. 16 is a view showing an example of a photoelectric conversion device using the light emitting device according to the embodiment;

FIG. 17 is a view showing an example of an electronic apparatus using the light emitting device according to the embodiment;

FIGS. 18A and 18B are views each showing an example of a display device using the light emitting device according to the embodiment;

FIG. 19 is a view showing an example of an illumination device using the light emitting device according to the embodiment;

FIG. 20 is a view showing an example of a moving body using the light emitting device according to the embodiment; and

FIGS. 21A and 21B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

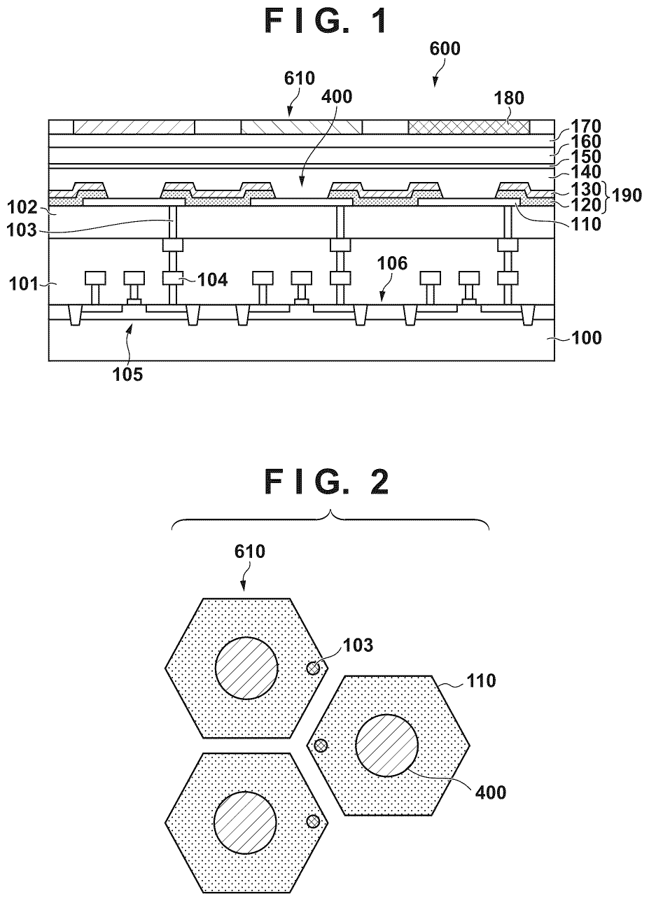

With reference to FIGS. 1 to 12, a light emitting device according to an embodiment of the present disclosure will be described. FIG. 1 is a sectional view showing an example of the arrangement of a light emitting device 600 according to this embodiment. The light emitting device 600 includes a plurality of light emitting elements 610. The light emitting element 610 includes an electrode 110 arranged on a main surface 106 of a substrate 100, a bank 190 arranged to cover the outer edge of the electrode 110 and provided with an opening portion 400 which exposes the electrode 110 inside the outer edge, an organic layer 140 arranged on the electrode 110, and an electrode 150 arranged to cover the organic layer 140. A description will be given below assuming that the electrode 110 functions as an anode and the electrode 150 functions as a cathode, but the electrode 110 may function as a cathode and the electrode 150 may function as an anode.

The light emitting element 610 can also include a moisture preventing layer 160 arranged to cover the electrode 150. The moisture preventing layer 160 protects components such as the organic layer 140 from moisture in the air and the like. A planarization layer 170 arranged to cover the moisture preventing layer 160, color filters 180 arranged on the planarization layer 170, and the like may further be arranged in the light emitting element 610. Insulating layers 101 and 102 are arranged between the substrate 100 and the light emitting element 610. A transistor of a driving circuit 105 arranged in the substrate 100 and the light emitting element 610 are connected via plugs 103 and wiring patterns 104 arranged in the insulating layers 101 and 102.

FIG. 2 is a plan view showing an example of the arrangement of the light emitting elements 610 in the light emitting device 600. To clarify the positional relationship, FIG. 2 illustrates the electrode 110, the plug 103 in contact with the electrode 110, and the opening portion 400 provided in the bank 190, and omits other components. In an orthogonal projection to the main surface 106 of the substrate 100, the electrode 110 may have a hexagonal shape as shown in FIG. 2, or may have another polygonal shape. For example, the electrode 110 may have a circular shape. In the orthogonal projection to the main surface 106 of the substrate 100, the opening portion 400 may have a circular shape as shown in FIG. 2, or may have a polygonal shape such as a hexagonal shape.

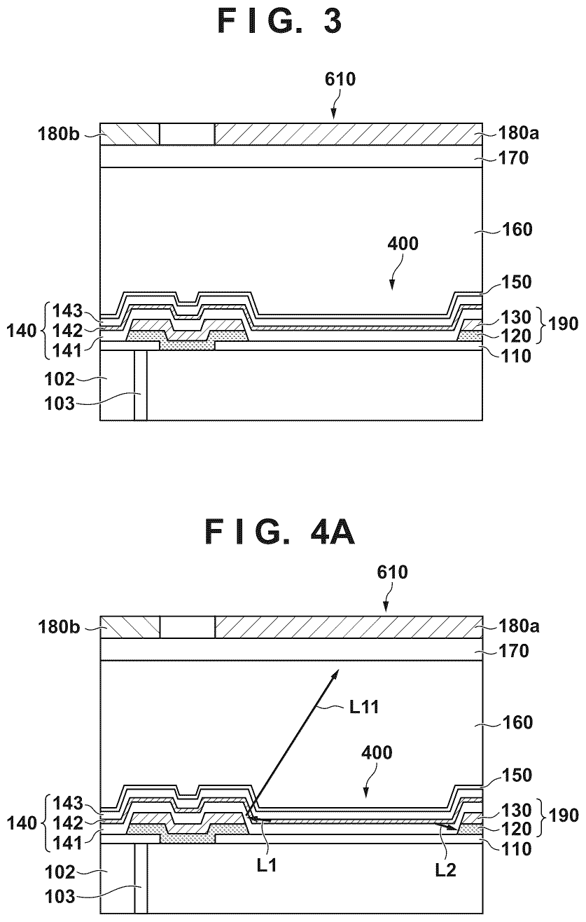

FIG. 3 is a partially enlarged view of FIG. 1. The organic layer 140 includes an organic layer 141 including at least one of a hole injection layer and a hole transport layer, an organic layer 142 functioning as a light emitting layer, and an organic layer 143 including at least one of an electron injection layer and an electron transport layer. The organic layer 140 is connected to the electrode 110 in the opening portion 400. The organic layer 141 is arranged on the electrode 110 and the bank 190, the organic layer 142 is arranged to cover the organic layer 141, and the organic layer 143 is arranged to cover the organic layer 142. The film thickness of each of the organic layers 141 to 143 can be, for example, 1 nm to 500 nm.

As shown in FIGS. 1 and 3, the organic layers 141 to 143 may be shared by a plurality of the light emitting elements 610. In other words, the organic layers 141 to 143 may be deposited as common layers in the light emitting region where the plurality of light emitting elements 610 are arranged, without being patterned for each light emitting element 610. In the arrangement shown in FIG. 3, each of the organic layers 141 to 143 is illustrated as one layer, but may have a stacked structure of two or more layers. For example, the organic layer 142 functioning as the light emitting layer may be formed by stacking organic layers of a plurality of light emission colors, thereby emitting white light. In this case, when white light is transmitted through the color filter 180, light of a predetermined wavelength such as red light, green light, or blue light is emitted.

As shown in FIGS. 1 and 3, the bank 190 has a stacked structure of a layer 120 made of the first material and a layer 130 made of the second material. The layer 120 is arranged between the layer 130 and the electrode 110. The layer 120 is a layer that has insulating property and absorbs more light emitted by the light emitting layer (organic layer 142) than the layer 130. Hereinafter, the layer 120 may be expressed as having light absorbability. The layer 130 is a layer that reflects more light emitted by the light emitting layer (organic layer 142) than the layer 120. Hereinafter, the layer 130 may be expressed as having light reflectivity.

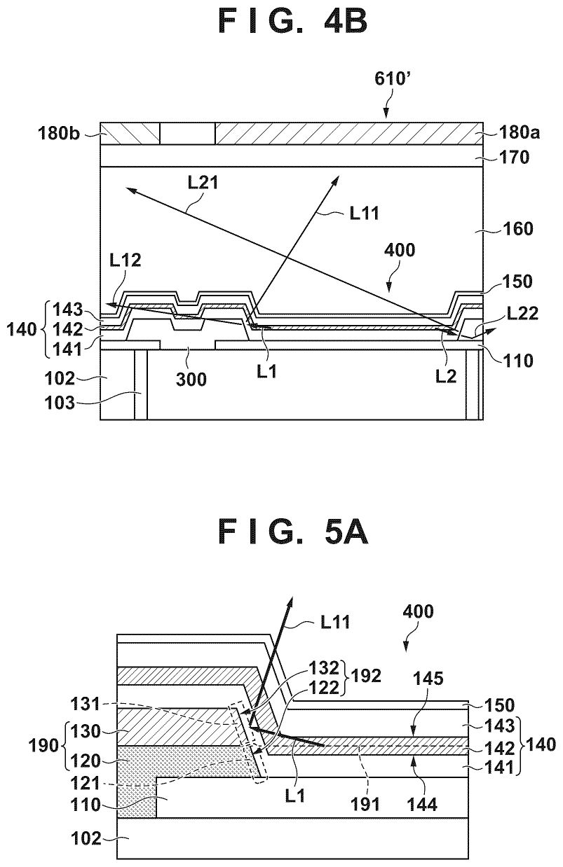

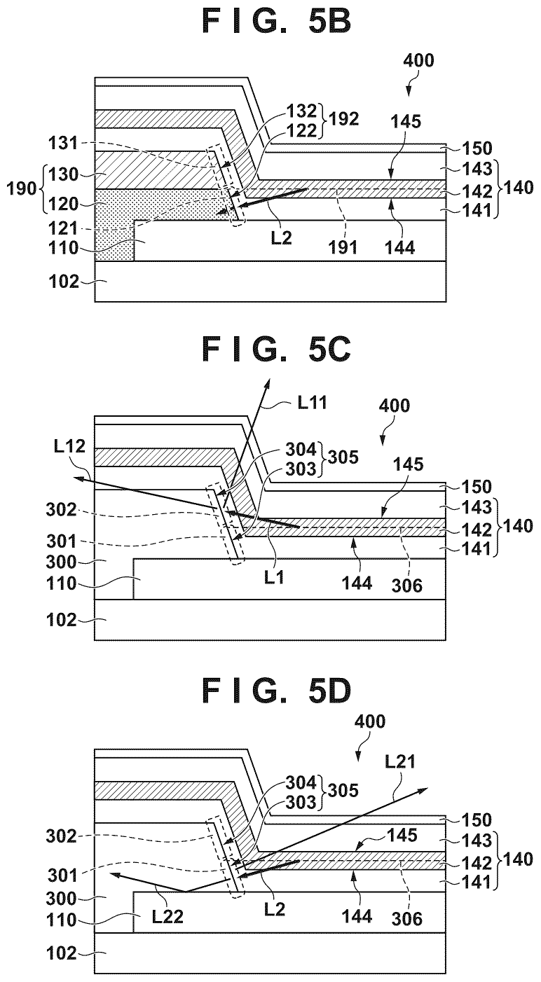

Next, problems of a light emitting element 610′ of a comparative example including a bank 300 made of a transparent material and the light emitting element described in US-2019-0027547 will be described, and then the effect of the bank 190 of the light emitting element 610 according to this embodiment will be described. FIGS. 4A, 5A, and 5B are views for explaining the bank 190 of this embodiment, and FIGS. 4B, 5C, and 5D are views for explaining the bank 300 of the comparative example.

In the light emitting element 610′ of the comparative example, a side surface 305 of the bank 300 facing the opening portion 400 has a surface 303 arranged in a lower portion 301 of the bank 300 and a surface 304 arranged in an upper portion 302 of the bank 300. Here, the boundary between the lower portion 301 (surface 303) and the upper portion 302 (surface 304) of the bank 300 is set as follows. A virtual line 306 passing through the boundary between the surface 303 and the surface 304 and parallel to the main surface 106 of the substrate 100 passes between a lower surface 144 and an upper surface 145 of a portion of the organic layer 142 functioning as the light emitting layer overlapping the center of the electrode 110 in the orthogonal projection to the main surface 106. Here, the center of the electrode 110 may be the geometric centroid position of the electrode 110 in the orthogonal projection to the main surface 106 of the substrate 100.

As shown in FIG. 5C, of the light emitted by the organic layer 142 and reaching the bank 300, upward light L1 reaches the surface 304 of the upper portion 302 of the bank 300. The light L1 becomes one of light L11 reflected at the surface 304, and light L12 that enters the bank 300 from the surface 304 and is transmitted through the bank 300. As shown in FIG. 4B, since the emission direction of the light L11 forms a large angle with the main surface 106 of the substrate 100, most components of the light L11 are emitted in the direction of a color filter 180a of the light emitting element 610 that has emitted the light. As a result, the light L11 is transmitted through the color filter 180a, thereby contributing to improvement of light extraction efficiency without causing light emission crosstalk. On the other hand, the light L12 is transmitted or guided through the bank 300, so that it is emitted in the direction of the adjacent light emitting element 610′. In this case, when the light L12 is transmitted through a color filter 180b of the adjacent light emitting element 610′, light emission crosstalk occurs.

As shown in FIG. 5D, of the light emitted by the organic layer 142 and reaching the bank 300, downward light L2 reaches the surface 303 of the lower portion 301 of the bank 300. The light L2 becomes one of light L21 reflected at the surface 303, and light L22 that enters the bank 300 from the surface 303 and is transmitted through the bank 300. As shown in FIG. 4B, since the emission direction of the light L21 forms a small angle with the main surface 106 of the substrate 100, most components of the light L21 are emitted in the direction of the color filter 180b of the adjacent light emitting element 610′. As a result, the light L21 is transmitted through the color filter 180b, and causes light emission crosstalk. On the other hand, the light L22 is transmitted or guided through the bank 300, so that it is emitted in the direction of the adjacent light emitting element 610′. In this case, when the light L22 is transmitted through the color filter 180b of the adjacent light emitting element 610′, light emission crosstalk occurs.

In this manner, in the light emitting element 610′ of the comparative example including the bank 300 made of a transparent material, from the light L1 and light L2 reaching the bank 300, the light L11 that contributes to improvement of light extraction efficiency, and the light L12, light L21, and light L22 that cause light emission crosstalk are generated. That is, the light L12, light L21, and light L22 cause deterioration of image quality of the light emitting device.

Next, consider the light emitting element disclosed in US-2019-0027547. In the light emitting element described in US-2019-0027547, a light blocking layer that absorbs light is provided on the entire side surface of a bank. In this structure, the above-described light L1 and light L2 reaching the bank are not reflected but absorbed. Thus, light emission crosstalk is suppressed. However, since the light L1 is absorbed, the above-described light L11 that contributes to improvement of light extraction efficiency without causing light emission crosstalk is not generated either. Therefore, this can lead to deterioration of light extraction efficiency.

Next, the effect of the bank 190 of the light emitting element 610 of this embodiment will be described. In this embodiment, as shown in FIGS. 5A and 5B, a side surface 192 of the bank 190 facing the opening portion 400 includes a surface 132 formed by a portion 131 of the layer 130 made of the second material, and a surface 122 formed by a portion 121 of the layer 120 arranged between the surface 132 and the electrode 110 and made of the first material different from the second material. As described above, the layer 130 reflects more light emitted by the light emitting layer (organic layer 142) than the layer 120. Hence, the portion 131 reflects more light emitted by the light emitting layer (organic layer 142) than the portion 121. On the other hand, the layer 120 is a layer that has insulating property and absorbs more light emitted by the light emitting layer (organic layer 142) than the layer 130. Hence, the portion 121 has insulating property and absorbs more light emitted by the light emitting layer (organic layer 142) than the portion 131.

As shown in FIGS. 5A and 5B, the layer 120 may include the portion 121 forming the surface 122, and the layer 130 may include the portion 131 forming the surface 132. Alternatively, for example, layers functioning as the portions 121 and 131, respectively, may be formed on the side surface of the bank made of a transparent material.

Similar to the above description, a virtual line 191 passing through the boundary between the surface 122 and the surface 132 of the side surface 192 of the bank 190 and parallel to the main surface 106 of the substrate 100 passes between the lower surface 144 and the upper surface 145 of a portion of the light emitting layer (organic layer 142) overlapping the center of the electrode 110 in the orthogonal projection to the main surface 106. In this case, as shown in FIG. 5A, of the light emitted by the organic layer 142 and reaching the bank 190, the upward light L1 reaches the surface 132 of the surface 192 of the bank 190. Since the layer 130 has light reflectivity, the light L1 is reflected without being transmitted through the portion 131 of the bank 190, and becomes the light L11. As shown in FIG. 4B, since the emission direction of the light L11 forms a large angle with the main surface 106 of the substrate 100, most components of the light L11 are emitted in the direction of the color filter 180a of the light emitting element 610 which has emitted light. As a result, the light L11 is transmitted through the color filter 180a, thereby contributing to improvement of light extraction efficiency without causing light emission crosstalk.

As shown in FIG. 5B, of the light emitted by the organic layer 142 and reaching the bank 190, the downward light L2 reaches the surface 122 of the side surface 192 of the bank 190. Since the layer 120 has light absorbability, the light L2 is absorbed by the layer 120 (portion 121) of the bank 190, so that generation of the light L21 and light L22 that cause light emission crosstalk can be suppressed.

As described above, in the light emitting element 610′ including the bank 300 made of a transparent material, the light L1 and light L2 having reached the bank 300 become the light L11 that contributes to improvement of light extraction efficiency, and the light L12, light L21, and light L22 that cause light emission crosstalk. In the light emitting element described in US-2019-0027547, the light L1 and light L2 having reached the bank are absorbed, so none of the light L11 that contributes to improvement of light extraction efficiency and the light L12, light L21, and light L22 that cause light emission crosstalk are generated.

On the other hand, in the light emitting element 610 including the bank 190 of this embodiment, generation of the light L12, light L21, and light L22 that cause light emission crosstalk is suppressed. In addition, since the layer 130 has light reflectivity, most components of the light L1 are reflected as the light L11. The bank 190 where the layers 120 and 130 are stacked can suppress light emission crosstalk, and generate the light L11, which contributes to improvement of light extraction efficiency, selectively and with high intensity as compared to the light emitting element 610 of the comparative example including the bank 300 made of a transparent material. That is, the light emitting device 600 including the light emitting element 610 to which the bank 190 of this embodiment is applied can achieve both suppression of light emission crosstalk and improvement of light extraction efficiency.

The position of the boundary between the surface 122 and the surface 132 in the side surface 192 of the bank 190 facing the opening portion 400 may appropriately be changed in accordance with various situations. For example, as described above, at the position overlapping the center of the electrode 110, the virtual line 191 passing through the boundary between the surface 122 and the surface 132 and parallel to the main surface 106 of the substrate 100 may pass between the surface (the lower surface 144 of the organic layer 142 functioning as the light emitting layer) where the organic layer 142 contacts the organic layer 141 and the surface (the upper surface 145 of the organic layer 142 functioning as the light emitting layer) where the organic layer 142 contacts the organic layer 143. The upward light L1 having reached the side surface 192 of the bank 190 can be reflected to the maximum extent as the light L11 that contributes to improvement of light extraction efficiency.

Alternatively, for example, at the position overlapping the center of the electrode 110, the virtual line 191 passing through the boundary between the surface 122 and the surface 132 and parallel to the main surface 106 of the substrate 100 may pass between the lower surface 144 of the organic layer 142 and the electrode 110 (pass through the organic layer 141). The more components of the light having reached the side surface 192 of the bank 190 are reflected, leading to further improvement of light extraction efficiency. Alternatively, for example, at the position overlapping the center of the electrode 110, the virtual line 191 passing through the boundary between the surface 122 and the surface 132 and parallel to the main surface 106 of the substrate 100 may pass through the organic layer 143. The more components of the light having reached the side surface 192 of the bank 190 are absorbed, leading to further suppression of light emission crosstalk.

The angle between the side surface 192 of the bank 190 and the surface of the electrode 110 may appropriately be set in accordance with various situations. Here, the surface of the electrode 110 can be the surface where the electrode 110 contacts the organic layer 140. The surface of the electrode 110 is the surface of the electrode 110 on the opposite side of the surface facing the substrate 100. For example, the side surface 192 of the bank 190 may have an internal angle of 60° or more and 90° or less with respect to the surface of the electrode 110. That is, the surface 122 formed by the layer 120 and the surface 132 formed by the layer 130 may have an internal angle of 60° or more and 90° or less with respect to the surface of the electrode 110. This allows the high aperture ratio of the light emitting element 610, thereby contributing to improvement of light emission efficiency. In addition, the organic layer 141 can be locally thinned and step disconnection thereof can be generated, so that a current leakage between the adjacent light emitting elements 610 can be suppressed. For example, the side surface 192 of the bank 190 may have an internal angle smaller than 60° with respect to the surface of the substrate 100. This can prevent the locally high resistance and step disconnection of the electrode 150.

Furthermore, for example, the surface 122 formed by the layer 120 and the surface 132 formed by the layer 130 may have different angles with respect to the surface of the electrode 110. For example, the surface 132 may have a smaller internal angle with respect to the surface of the electrode 110 than the surface 122. For example, the surface 132 may have an internal angle smaller than 60° with respect to the surface of the electrode 110, and the surface 122 may have an internal angle of 60° or more and 90° or less with respect to the surface of the electrode 110. This can allow the high aperture ratio of the light emitting element 610 and suppress the locally high resistance and step disconnection of the electrode 150.

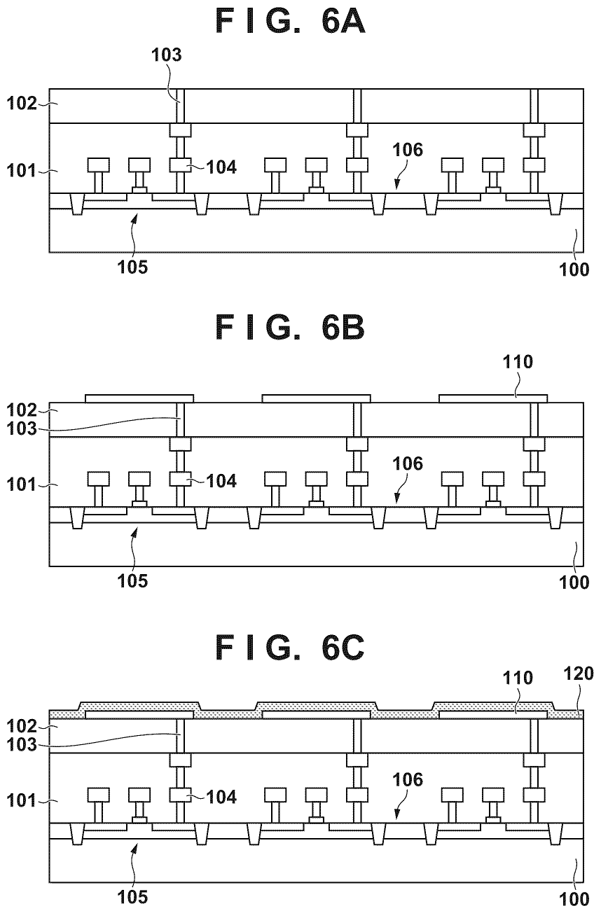

Next, with reference to FIGS. 6A to 8C, a manufacturing method of the light emitting device 600 including the light emitting elements 610 according to this embodiment will be described. First, the substrate 100 that includes the driving circuit 105 including transistors and the like formed using a known MOS process is prepared. The insulating layer 101 is formed on the substrate 100. Then, by using a plasma CVD method or the like, an insulating film made of, for example, silicon oxide or silicon oxynitride is deposited to form the insulating layer 102. The surface of the insulating layer 102 including the light emitting region where the plurality of the light emitting elements 610 are to be arranged may be planarized using a CMP method or the like. After the insulating layer 102 is formed, a plurality of vias are formed at predetermined positions in the insulating layer 102 using a photolithography method, a dry etching method, and the like. Then, for example, a conductive material such as tungsten is deposited, and the extra conductive material is removed using a CMP method, an etch back method, or the like, thereby forming the plugs 103 as shown in FIG. 6A.

Then, for example, by using a sputtering method, a conductive film for forming the electrodes 110 is formed on the insulating layer 102. For example, the conductive film may be a metal film formed by stacking titanium, titanium nitride, an aluminum alloy, and titanium in this order. Alternatively, the conductive film may be a transparent conductive film made of indium tin oxide or the like. Then, the conductive film is patterned into a predetermined shape using a photolithography method, or a dry etching method, a wet etching method, and the like in accordance with the material, thereby forming the electrodes 110 connected to the plugs 103 as shown in FIG. 6B.

After the electrodes 110 are formed, as shown in FIG. 6C, the layer 120 constituting the bank 190 is formed to cover the insulating layer 102 and the electrodes 110. Various materials having light absorbability are used for the layer 120. For the layer 120, a material that absorbs some or all of the wavelengths in the visible light region (360 nm to 830 nm) is used. For example, as the material for the layer 120, a metal oxide such as chromium oxide (CrₓO_{y}), a metal nitride such as tantalum nitride (TaN) or manganese nitride (Mn₂N) may be used. Further, as the material for the layer 120, various resins like a resin added with a black pigment such as carbon black or a resin added with a black dye may be used. The layer 120 can be formed using a method suitable for the material to be used, such as a vacuum vapor deposition method, a sputtering method, a spin coating method, or a slit coating method.

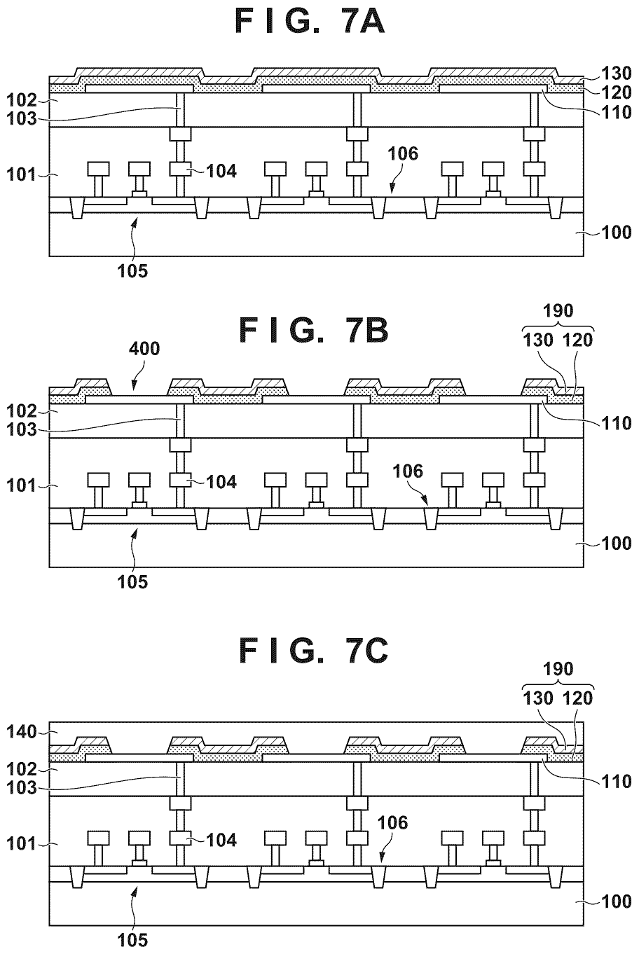

Then, as shown in FIG. 7A, the layer 130 constituting the bank 190 is formed to cover the layer 120. Various materials having light reflectivity are used for the layer 130. For example, a material having a reflectance of 80% or more in a visible light region may be used as the material for the layer 130. More specifically, examples of the material for the layer 130 are a high reflectance material such as aluminum, silver, or platinum, and an alloy containing the high reflectance material (for example, such as AlCu). The layer 130 can be formed using a method suitable for the material to be used, such as a vacuum vapor deposition method or a sputtering method.

After the layers 120 and 130 are formed, as shown in FIG. 7B, the layers 120 and 130 are patterned into a predetermined shape using a photolithography method, a dry etching method, and the like, thereby forming the opening portion 400 on each electrode 110. Thus, the bank 190 is formed.

Then, as shown in FIG. 7C, the organic layer 140 is formed using, for example, a vacuum vapor deposition method or the like. As the organic layer 140, for example, the organic layer 141 having a lower resistance than the light emitting layer, such as a hole injection layer or a hole transport layer, the organic layer 142 functioning as the light emitting layer, and the organic layer 143 such as an electron transport layer may be sequentially stacked. As the vacuum vapor deposition method, for example, a rotation vapor deposition method, a line vapor deposition method, a transfer vapor deposition method, or the like may be used. As the organic layer 140, for example, a hole injection layer/a hole transport layer/a light emitting layer/a charge generation layer/a light emitting layer/an electron transport layer may be stacked from the electrode 110 side.

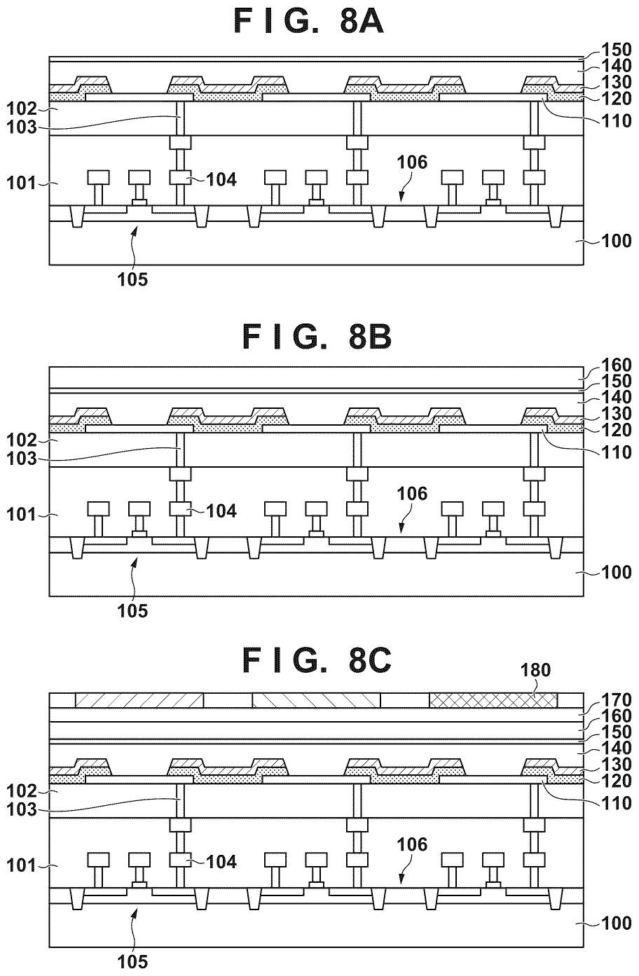

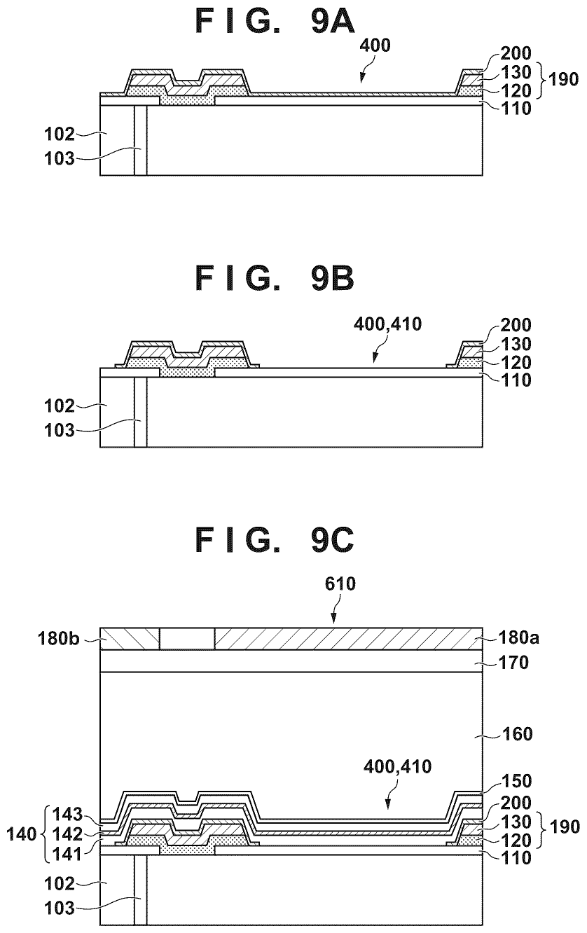

After the organic layer 140 is formed, the electrode 150 is formed as shown in FIG. 8A. As the electrode 150, for example, a transparent conductive film made of indium tin oxide or the like may be formed using a vacuum vapor deposition method. After the organic layer 140 is formed, the electrode 150 may be formed without releasing the decompressed atmosphere upon forming the organic layer 140 to the atmosphere.

Then, as shown in FIG. 8B, the moisture preventing layer 160 is deposited to cover the electrode 150 using, for example, a plasma CVD method, a sputtering method, an ALD method, or the like. The deposition temperature of the moisture preventing layer 160 may be equal to or lower than the decomposition temperature of the organic material forming the organic layer 140, for example, be equal to or lower than 120° C.

After the moisture preventing layer 160 is formed, as shown in FIG. 8C, for example, the material for a color filter that transmits red light is applied on the moisture preventing layer 160 and patterned using a photolithography method, thereby forming a color filter that transmits red light. Then, similar to the color filter that transmits red light, a color filter that transmits green light and a color filter that transmits blue light are formed. Thus, the color filters 180 are formed.

As shown in FIG. 8C, the transparent planarization layer 170 for improving the adhesiveness between each color filter 180 and the moisture preventing layer 160 may be provided between the color filters 180 and the moisture preventing layer 160. Thereafter, although not shown, terminals for transmitting and receiving signals between the light emitting device 600 and the outside, and the like are formed into predetermined shapes using a photolithography method, a dry etching method, and the like. By including the above-described steps, the light emitting device 600 that includes the light emitting elements 610 each including the bank 190 according to this embodiment is formed.

FIGS. 9A to 9C are views showing a modification of the above-described light emitting element 610 and a manufacturing method thereof. The arrangement different from the above-described embodiment will mainly be described, and a description of the arrangement that may be similar to the above-described embodiment will be omitted, as appropriate. Similar to FIG. 3, FIGS. 9A to 9C do not show the components arranged on the substrate 100 side of the insulating layer 102. As shown in FIG. 9C, an insulating layer 200 covering the bank 190 is further arranged in the light emitting element 610 according to this embodiment.

In the light emitting element 610′ of the comparative example shown in FIG. 4B, each light emitting element 610′ is electrically isolated by the bank 300 having insulating property. Hence, each light emitting element 610′ can independently be driven to emit light. This also applies to the above-described light emitting element 610 according to this embodiment shown in FIG. 3. However, since the organic layer 141 including at least one of a hole injection layer and a hole transport layer has a lower resistance than the organic layer 142 functioning as the light emitting layer, charges may move between the light emitting elements 610 via the organic layer 141. Furthermore, in the light emitting element 610 shown in FIG. 3, the layer 130 has light reflectivity, but many materials having light reflectivity often have electrical conductivity as well. Hence, if charges moving via the organic layer 141 reach the layer 130, a current leakage to the adjacent light emitting element 610 via the layer 130 may occur.

To prevent this, like the light emitting element 610 according to this embodiment shown in FIG. 9C, the insulating layer 200 is provided to cover the side surface of the layer 120 and the side and upper surfaces of the layer 130, which constitute the bank 190. This can prevent the charge having moved via the organic layer 141 from reaching the layer 130.

The insulating layer 200 can be formed of a transparent material. If the insulating layer 200 is formed of a transparent material, light reaching the surface of the insulating layer 200 reaches the layers 120 and 130. In this case, the above-described effect can be exhibited.

The refractive index of the insulating layer 200 may be similar to the refractive index of the organic layer 141. This is so because, if the difference between the refractive index of the insulating layer 200 and the refractive index of the organic layer 141 is large, light is reflected at the interface between the organic layer 141 and the insulating layer 200, so the above-described effect cannot be sufficiently exhibited. Examples of the material for the insulating layer 200 are insulating materials such as silicon oxide, silicon oxynitride, and silicon nitride. However, the material is not limited to this, and a suitable insulating material may be used in accordance with the refractive index of the material for the organic layer 141.

The end portion of the insulating layer 200 may have an internal angle of 90° or less with respect to the surface of the electrode 110. Furthermore, the side surface of the end portion of the insulating layer 200 may form an acute angle with the surface of the electrode 110. This can suppress a locally high resistance and step disconnection of the electrode 150 arranged on the insulating layer 200 via the organic layer 140.

Subsequentially, the manufacturing procedure of the light emitting element 610 including the insulating layer 200 will be described. First, by using steps similar to those shown in FIGS. 6A to 7B described above, the bank 190 provided with the opening portion 400 on the electrode 110 is formed. Then, as shown in FIG. 9A, the insulating layer 200 is deposited using, for example, a plasma CVD method or the like. Furthermore, as shown in FIG. 9B, the insulating layer 200 is patterned into a predetermined shape by using a photolithography method, a dry etching method, or the like, thereby forming a corresponding opening portion 410 on the electrode 110. The subsequent steps are similar to the steps described above with reference to FIGS. 7C to 8C. By including the above-described steps, the light emitting element 610 that includes the insulating layer 200 covering the bank 190 as shown in FIG. 9C is formed.

Also in the light emitting element 610 according to this embodiment, both suppression of light emission crosstalk and improvement of light extraction efficiency can be achieved by the bank 190 including the layers 120 and 130. Furthermore, since the insulating layer 200 covers the bank 190, a current leakage between the light emitting elements 610 is suppressed. As a result, unintended light emission and unintended luminance change caused by a current leakage between the light emitting elements 610 are suppressed, and the image quality of the light emitting device 600 can improve.

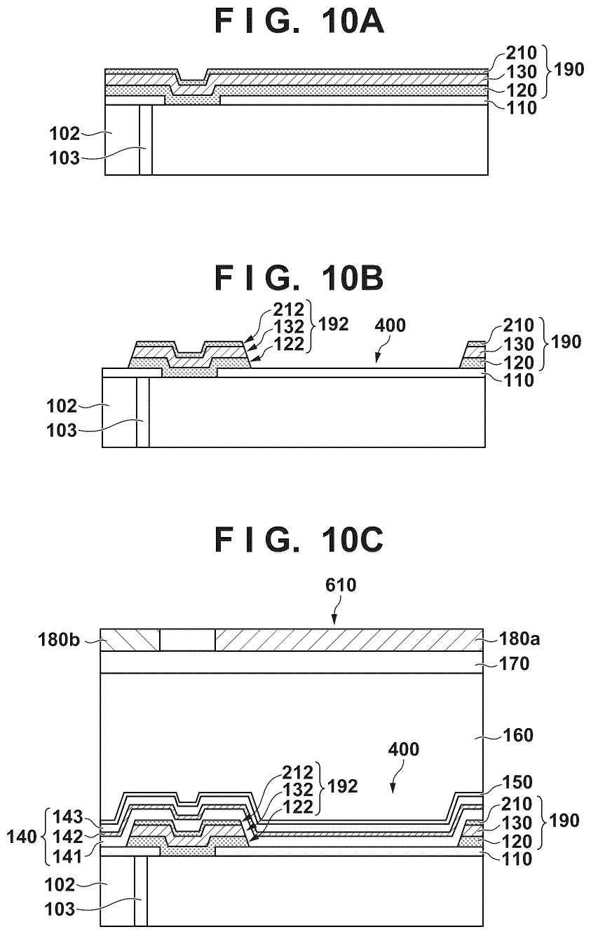

FIGS. 10A to 10C are views showing a modification of the above-described light emitting element 610 and a manufacturing method thereof. The arrangement different from the above-described embodiment will mainly be described, and a description of the arrangement that may be similar to the above-described embodiment will be omitted, as appropriate. Similar to FIG. 3 and FIGS. 9A to 9C, FIGS. 10A to 10C do not show the components arranged on the substrate 100 side of the insulating layer 102. As shown in FIG. 10C, the bank 190 has a stacked structure including a layer 210 on the layer 130 in addition to the layers 120 and 130 in the light emitting element 610 according to this embodiment. It can also be said that, in addition to the above-described surfaces 122 and 132, the side surface 192 of the bank 190 facing the opening portion 400 further includes a surface 212 formed by a portion made of the third material different from the first material forming the layer 120. The surface 132 is arranged between the surface 212 and the surface 122.

The portion forming the surface 132 of the layer 130 having light reflectivity reflects more light emitted by the light emitting layer (organic layer 142) than the portion forming the surface 212 of the layer 210 made of the third material. On the other hand, the portion forming the surface 212 of the layer 210 absorbs more light emitted by the light emitting layer (organic layer 142) than the portion forming the surface 132 of the layer 130. Accordingly, it may be expressed that the layer 210 has light absorbability like the layer 120. For example, the layer 210 may be formed of the same material as the layer 120.

In the light emitting device 600 including the light emitting element 610, the image quality of the light emitting device 600 may deteriorate due to internal reflection of external light. In the arrangement of the light emitting element 610 shown in FIG. 3, the layer 130 has light reflectivity. Therefore, external light may be reflected at the upper surface of the layer 130, leading to deterioration of the image quality of the light emitting device 600. To prevent this, like the light emitting element 610 shown in FIG. 10C, the layer 210 having light absorbability is arranged on the layer 130. This can suppress reflection of external light at the bank 190. As a result, the image quality of the light emitting device 600 can improve.

The length of the surface 212 of the layer 210 in the normal direction of the main surface 106 of the substrate 100 (that is, the film thickness of the layer 210) may be smaller than the length of the surface 132 of the layer 130 in the normal direction of the main surface 106 (that is, the film thickness of the layer 130). This can suppress a decrease in the amount of light reflected as the light L11, of the upward light L1 reaching the side surface 192 of the bank 190, that contributes to improvement of light extraction efficiency. For example, the film thickness of the layer 210 may be ½ or less, ⅓ or less, or ⅕ or less the film thickness of the layer 130. The thickness of the layer 210 can appropriately be set in accordance with the degree of absorption of external light.

Subsequently, the manufacturing procedure of the light emitting element 610 that includes the bank 190 including the layers 120, 130, and 210 will be described. First, the process up to deposition of the layer 130 is performed using steps similar to those shown in FIGS. 6A to 7A described above. Then, as shown in FIG. 10A, the layer 210 is formed using a method suitable for the material used for the layer 210, such as a vacuum vapor deposition method, a sputtering method, a spin coating method, a slit coating method, or the like. Furthermore, as shown in FIG. 10B, the layers 120, 130, and 210 are patterned into a predetermined shape using a photolithography method, a dry etching method, and the like. Thus, the bank 190 having a stacked structure including the layers 120, 130, and 210 and provided with the opening portion 400 on the electrode 110 is formed. Then, as shown in FIG. 7C, the organic layer 140, the electrode 150, the moisture preventing layer 160, the planarization layer 170, and the color filters 180 are formed by the methods described in the first embodiment. Subsequent steps are similar to the steps described with reference to FIGS. 7C to 8C described above. By including the above-described steps, the light emitting element 610 that includes the bank 190 including the layers 120, 130, and 210 as shown in FIG. 10C is formed.

Also in the light emitting element 610 according to this embodiment, both suppression of light emission crosstalk and improvement of light extraction efficiency can be achieved by the bank 190. Furthermore, the bank 190 that includes the layer 210 having light absorbability arranged on the layer 130 can suppress deterioration of the image quality caused by external light entering the light emitting element 610. Although not shown in FIG. 10C, the insulating layer 200 covering the bank 190 may be arranged as in the arrangement shown in FIG. 9C. This can suppress a current leakage between the light emitting elements 610, thereby further improving the image quality of the light emitting device 600.

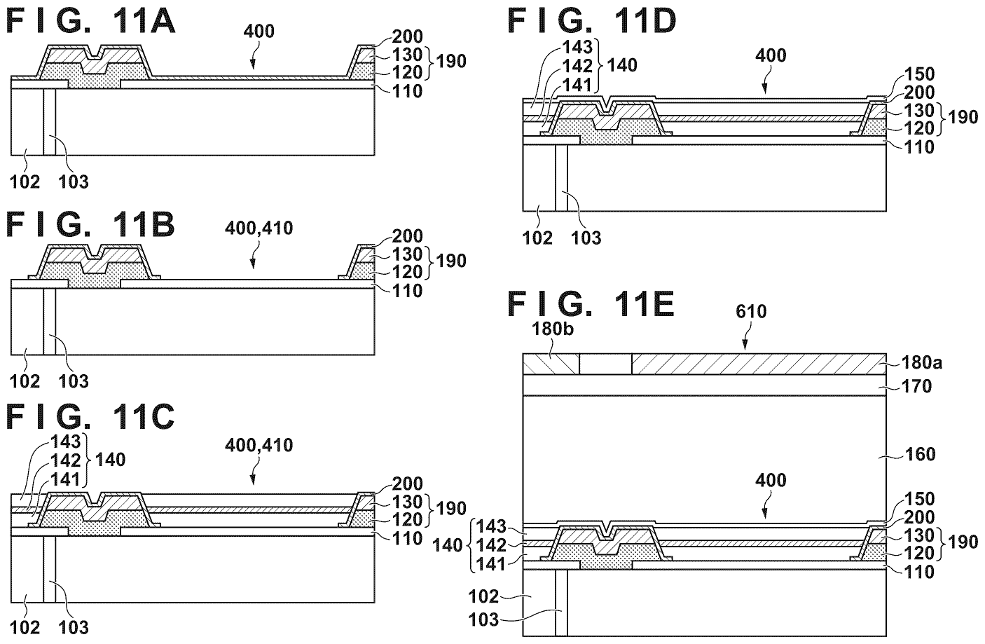

FIGS. 11A to 11E are views showing a modification of the above-described light emitting element 610 and a manufacturing method thereof. The arrangement different from the above-described embodiment will mainly be described, and a description of the arrangement that may be similar to the above-described embodiment will be omitted, as appropriate. Similar to FIG. 3, FIGS. 9A to 9C, and FIGS. 10A to 10C, FIGS. 11A to 11E do not show the components arranged on the substrate 100 side of the insulating layer 102. As shown in FIG. 11E, the organic layer 140 is independently arranged for each of the plurality of the light emitting elements 610 in the light emitting element 610 according to this embodiment.

As shown in FIG. 11E, in the light emitting element 610 according to this embodiment, the organic layer 140 is arranged to be embedded in the opening portion 400. Similar to the arrangement shown in FIG. 9C, the insulating layer 200 is provided to cover the bank 190. By arranging the organic layer 140 only in the opening portion 400 as in this embodiment, a current leakage between the adjacent light emitting elements 610 via the organic layer 141 having a lower resistance than the organic layer 142 functioning as the light emitting layer is suppressed.

In the structure as shown in FIG. 11E, if the insulating layer 200 is not provided, the layer 130 may contact the electrode 150. The layer 130 has light reflectivity, but many materials having light reflectivity often have electrical conductivity as well. Hence, if the layer 130 is in contact with the electrode 150, charges may move from the electrode 150 to the layer 130. In this case, electrons may not be efficiently injected into the organic layer 142 functioning as the light emitting layer, leading to a deterioration in performance of the light emitting element 610 such as a rise of the driving voltage. To prevent this, as in this embodiment, the insulating layer 200 is provided to cover the bank 190. This can suppress charges moving from the electrode 150 to the layer 130.

Subsequently, the manufacturing procedure of the light emitting element 610 shown in FIG. 11E will be described. First, by using steps similar to those shown in FIGS. 6A to 7B described above, the bank 190 provided with the opening portion 400 on the electrode 110 is formed. Then, as shown in FIG. 11A, the insulating layer 200 is deposited using, for example, a plasma CVD method or the like. Furthermore, as shown in FIG. 11B, the insulating layer 200 is patterned into a predetermined shape using a photolithography method, a dry etching method, and the like, thereby forming the corresponding opening portion 410 on the electrode 110.

After the bank 190 and the insulating layer 200 are formed, as shown in FIG. 11C, the organic layer 141, the organic layer 142, and the organic layer 143 are formed as the organic layer 140 in the opening portion 400 by, for example, a vacuum vapor deposition method using a mask. Then, as shown in FIG. 11D, the electrode 150 is formed. After the organic layer 140 is formed, the electrode 150 may be formed without releasing the decompressed atmosphere upon forming the organic layer 140 to the atmosphere. Subsequent steps are similar to the steps described above with reference to FIGS. 8B and 8C. By including the above-described steps, the light emitting element 610 as shown in FIG. 11E is formed.

Also in the light emitting element 610 according to this embodiment, both suppression of light emission crosstalk and improvement of light extraction efficiency can be achieved by the bank 190. Furthermore, since the organic layer 140 is arranged for each light emitting element 610, a current leakage between the light emitting elements 610 can be suppressed, and the image quality of the light emitting device 600 can improve.

Also in the arrangement shown in FIG. 11E in which the organic layer 140 is arranged for each light emitting element 610, the bank 190 may have the arrangement including the layer 210 in addition to the layers 120 and 130 as shown in FIG. 10C. In this case, if the layer 210 has insulating property and the layer 130 (the surface 132 formed by the layer 130) is not in contact with the electrode 150, the insulating layer 200 may not be arranged. This is because the layer 210 included in the bank 190 has an effect similar to that of the above-described insulating layer 200 arranged between the electrode 150 and the layer 130.

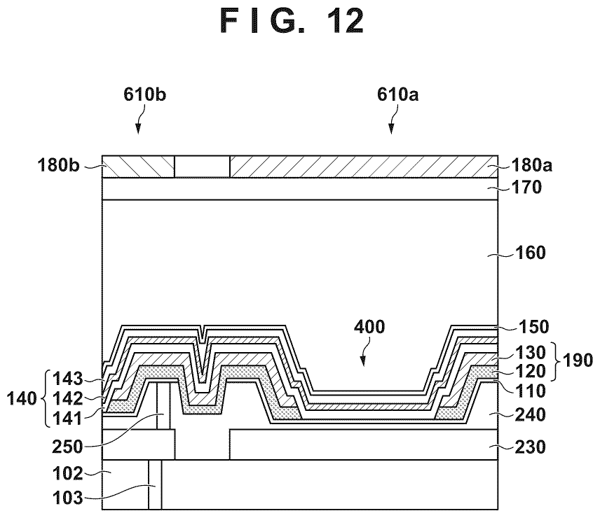

FIG. 12 is a view showing a modification of the light emitting element 610 described above. The arrangement different from the above-described embodiment will mainly be described, and a description of the arrangement that may be similar to the above-described embodiment will be omitted, as appropriate. Similar to FIG. 3, FIGS. 9A to 9C, FIGS. 10A to 10C, and FIGS. 11A to 11E, FIG. 12 does not show the components arranged on the substrate 100 side of the insulating layer 102. As shown in FIG. 12, the light emitting element 610 according to this embodiment includes an optical resonator structure.

The light emitting element 610 shown in FIG. 12 includes, between the electrode 110 and the main surface 106 of the substrate 100, a reflective layer 230 that reflects light emitted by the light emitting layer (organic layer 142), and the electrode 110 transmits light emitted by the light emitting layer (organic layer 142). Light emitted from the light emitting layer (organic layer 142) is transmitted through the transparent electrode 110, and the transmitted light is reflected at the reflective layer 230. The light emitted from the light emitting layer (organic layer 142) and the reflected light interfere and strengthen each other, thereby improving the light emission efficiency of the light emitting element 610.

As shown in FIG. 12, the reflective layer 230 is arranged on the insulating layer 102. An insulating layer 240 is provided to cover the insulating layer 102 and the reflective layer 230. The reflective layer 230 and the electrode 110 are electrically connected via the plug 250. In some light emitting elements 610 arranged in the light emitting device 600, the reflective layer 230 may be in direct contact with the electrode 110.

In the light emitting element 610, the film thickness of the insulating layer 240 arranged between the electrode 110 and the reflective layer 230, more specifically, the film thickness of the insulating layer 240 arranged in a region overlapping the opening portion 400 in the orthogonal projection to the main surface 106 of the substrate 100 is also referred to as an optical adjustment film thickness. For example, the optical adjustment film thickness is adjusted such that the light emitted from the light emitting layer (organic layer 142) and the light reflected at the reflective layer 230 interfere and strengthen each other. If the light emitting device 600 includes multiple light emitting elements 610 that emit different colors, the optical adjustment film thickness of the insulating layer 240 may change in accordance with the color of light emitted by the light emitting element 610. As shown in FIG. 12, the length between the electrode 110 and the reflective layer 230 (the optical adjustment film thickness of the insulating layer 240) in a light emitting element 610a may be different from the length between the electrode 110 and the reflective layer 230 (the optical adjustment film thickness of the insulating layer 240) in a light emitting element 610b.

Also in the light emitting element 610 using the optical resonator structure, both suppression of light emission crosstalk and improvement of light extraction efficiency can be achieved by the bank 190. Light may travel in the direction of the adjacent light emitting element 610 via the insulating layer 240. Even in this case, when the light reaches the lower surface of the layer 120, it is absorbed by the layer 120, so that light emission crosstalk is suppressed.

The light emitting element 610 having the optical resonator structure shown in FIG. 12 can be manufactured by using a known method for manufacturing a light emitting element having an optical resonator structure and a light emitting device, and the above-described manufacturing method. The components such as the insulating layer 200, the layer 210, the organic layer 140 provided independently for each light emitting element 610 may be applied to the light emitting element 610 having the optical resonator structure shown in FIG. 12.

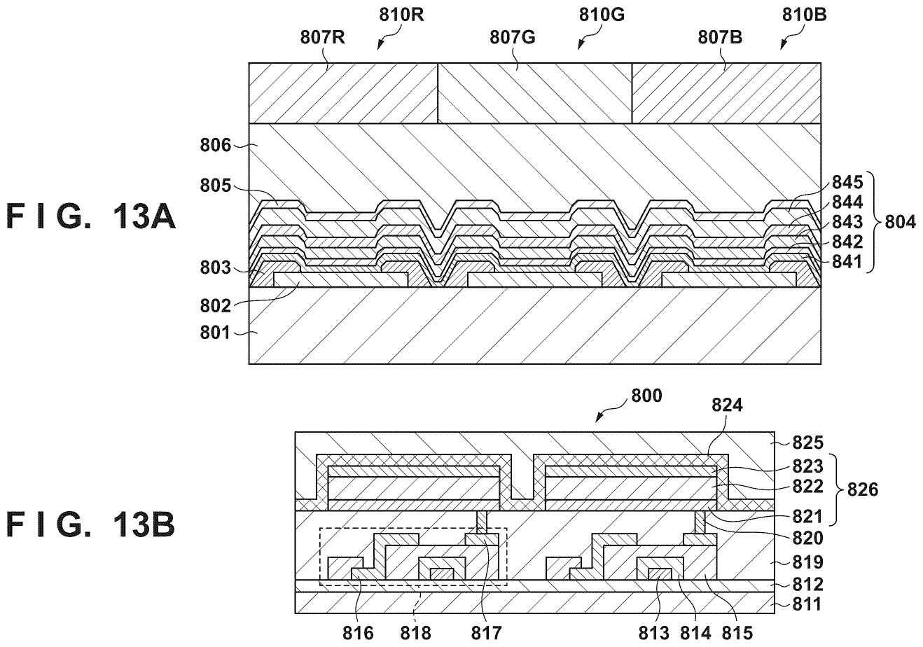

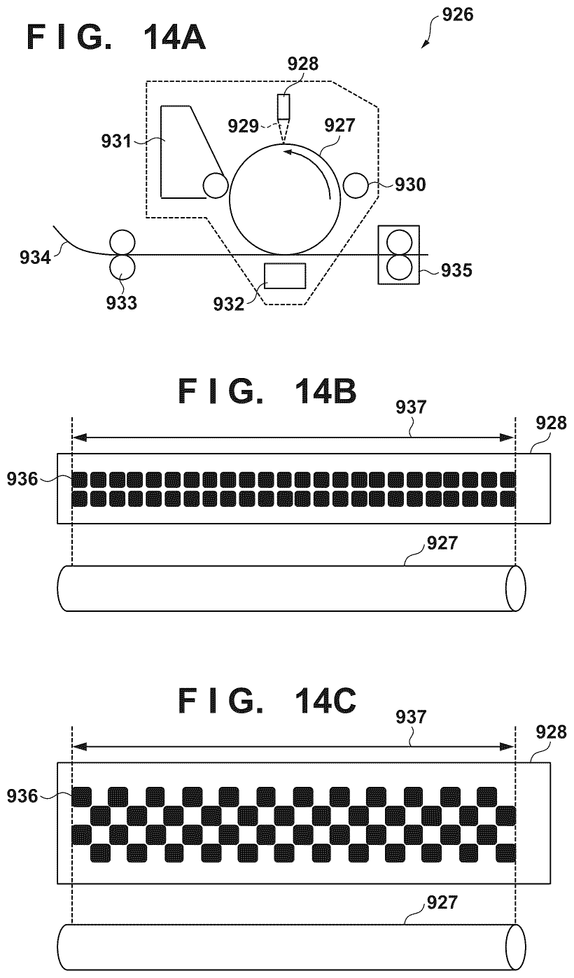

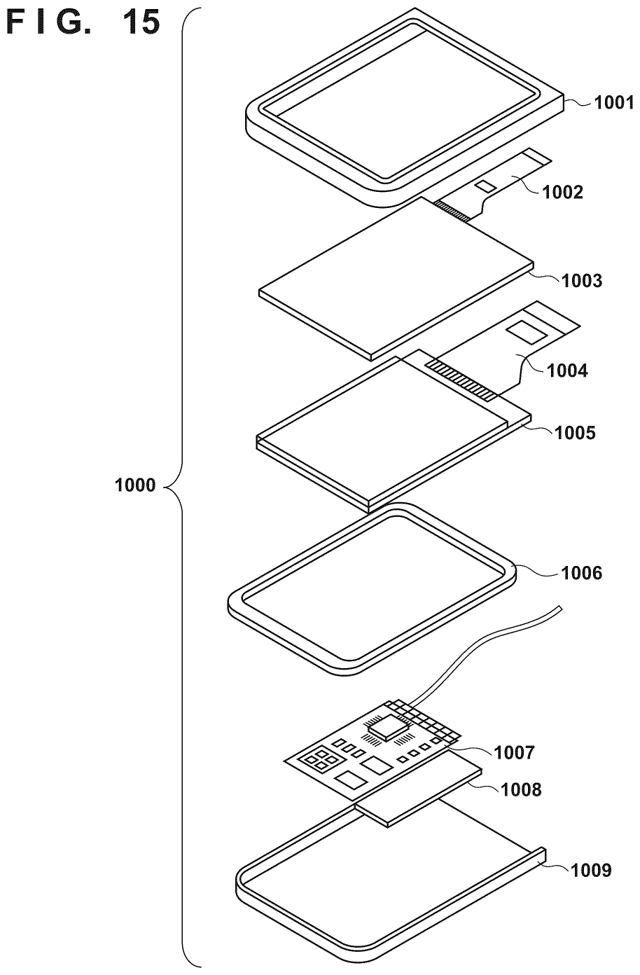

Here, application examples in which the light emitting device 600 according to this embodiment is applied to an image forming device, a display device, a photoelectric conversion device, an electronic apparatus, an illumination device, a moving body, and a wearable device will be described with reference to FIGS. 13A to 21B. The description will be given assuming that, for example, the above-described light emitting element 610 such as an organic EL element using an organic light emitting material is arranged in the pixel arranged in the light emitting device 600. Details of each component arranged in the pixel of the light emitting device 600 described above will be described first, and the application examples will be described after that.

### Arrangement of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in an arrangement including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this arrangement, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 13A shows an example of the pixel arranged in the light emitting device 600. The pixel includes sub-pixels 810 (corresponding to the above-described light emitting element 610). The sub-pixels are divided into sub-pixels 810R, 810G, and 810B based on the light emission color. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

A display device 800 (corresponding to the above-described light emitting device 600) shown in FIG. 13B is provided with an organic light emitting element 826 as an example of the light emitting element and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 13B. That is, one of the anode and cathode and one of the source electrode and drain electrode of the TFT are electrically connected. The TFT indicates a thin-film transistor.

In the display device 800 shown in FIG. 13B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 13B but may be used as another switching element.

The transistor used in the display device 800 shown in FIG. 13B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 13B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

FIGS. 14A to 14C are schematic views showing an example of an image forming device using the light emitting device 600 according to this embodiment. An image forming device 926 shown in FIG. 14A includes a photosensitive member 927, an exposure light source 928, a developing unit 931, a charging unit 930, a transfer device 932, a conveyance unit 933 (a conveyance roller in the arrangement shown in FIG. 14A), and a fixing device 935.

Light 929 is emitted from the exposure light source 928, and an electrostatic latent image is formed on the surface of the photosensitive member 927. The light emitting device 600 can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 14B and 14C is a schematic view showing a form in which a plurality of light emitting units 936 are arranged in the exposure light source 928 along the longitudinal direction of a long substrate. The light emitting device 600 can be applied to each of the light emitting units 936. That is, a plurality of the pixels are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 14B shows a form in which the light emitting units 936 are arranged along the long-axis direction of the photosensitive member 927. FIG. 14C shows a form, which is a modification of the arrangement of the light emitting units 936 shown in FIG. 14B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The arrangement of the light emitting units 936 shown in FIG. 14C can be referred to as, for example, an arrangement in a grid pattern, an arrangement in a staggered pattern, or an arrangement in a checkered pattern.

FIG. 15 is a schematic view showing an example of the display device using the light emitting device 600 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 600 can be applied to the display panel 1005. The pixels each including the light emitting element 610 arranged in the light emitting device 600 functioning as the display panel 1005 operate in a state in which they are connected to a control circuit including the active elements such as transistors arranged on the circuit board 1007.

The display device 1000 shown in FIG. 15 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

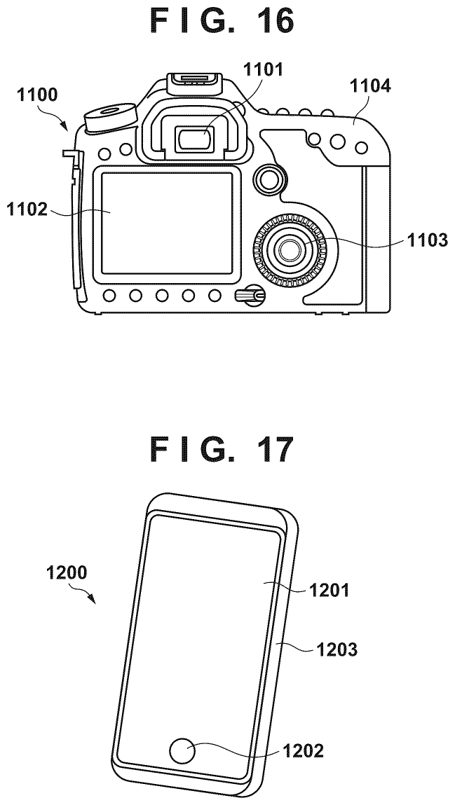

FIG. 16 is a schematic view showing an example of the photoelectric conversion device using the light emitting device 600 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 600 according to this embodiment can be applied to the viewfinder 1101 or the rear display 1102 as a display unit. In this case, the light emitting device 600 can display not only an image to be captured but also environment information, image capturing instructions, and the like. Examples of the environment information are the intensity and direction of external light, the moving velocity of an object, and the possibility that an object is covered with an obstacle.

Since the timing suitable for image capturing is a very short time in many cases, it is better to display the information as soon as possible. Therefore, the light emitting device 600 in which the pixel including the light emitting element 610 using the organic light emitting material such as an organic EL element is arranged may be used for the viewfinder 1101 or the rear display 1102. This is so because the organic light emitting material has a high response speed. The light emitting device 600 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 600 may be applied to a display unit of an electronic apparatus. At this time, the display unit can have both a display function and an operation function. Examples of the portable terminal are a portable phone such as a smartphone, a tablet, and a head mounted display.

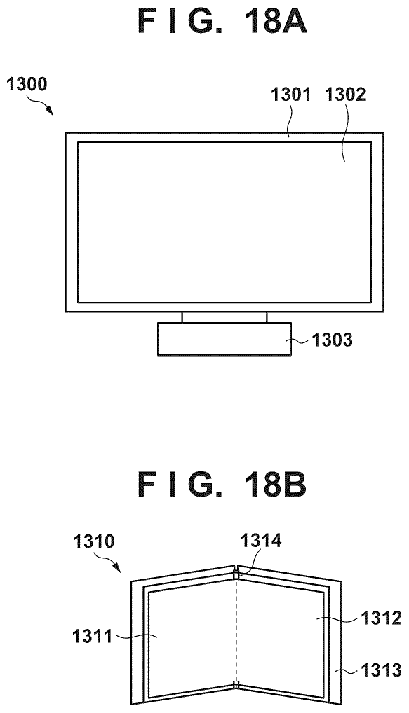

FIG. 17 is a schematic view showing an example of an electronic apparatus using the light emitting device 600 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 600 according to this embodiment can be applied to the display unit 1201.

FIGS. 18A and 18B are schematic views showing examples of the display device using the light emitting device 600 according to this embodiment. FIG. 18A shows a display device such as a television monitor or a PC monitor. A display device 1300 includes a frame 1301 and a display unit 1302. The light emitting device 600 according to this embodiment can be applied to the display unit 1302. The display device 1300 can include a base 1303 that supports the frame 1301 and the display unit 1302. The base 1303 is not limited to the form shown in FIG. 18A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 18B is a schematic view showing another example of the display device using the light emitting device 600 according to this embodiment. A display device 1310 shown in FIG. 18B can be folded, and is a so-called foldable display device. The display device 1310 includes a first display unit 1311, a second display unit 1312, a housing 1313, and a bending point 1314. The light emitting device 600 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

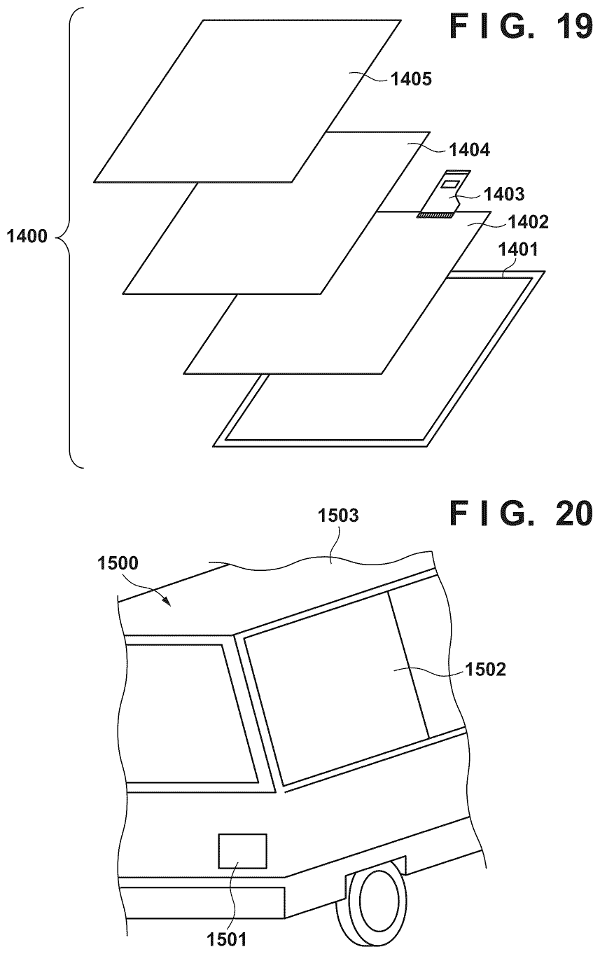

FIG. 19 is a schematic view showing an example of the illumination device using the light emitting device 600 according to this embodiment. An illumination device 1400 can include a housing 1401, a light source 1402, a circuit board 1403, an optical film 1404, and a light diffusing unit 1405. The light emitting device 600 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 600 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 20 is a schematic view of an automobile having a taillight as an example of a vehicle lighting appliance using the light emitting device 600 according to this embodiment. An automobile 1500 has a taillight 1501, and can have a form in which the taillight 1501 is turned on when performing a braking operation or the like. The light emitting device 600 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 600 according to this embodiment can be applied to the taillight 1501. The taillight 1501 can include a protection member for protecting the light emitting device 600 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 600 according to this embodiment may be used. In this case, the constituent materials of the electrodes and the like of the light emitting device 600 are formed by transparent members.

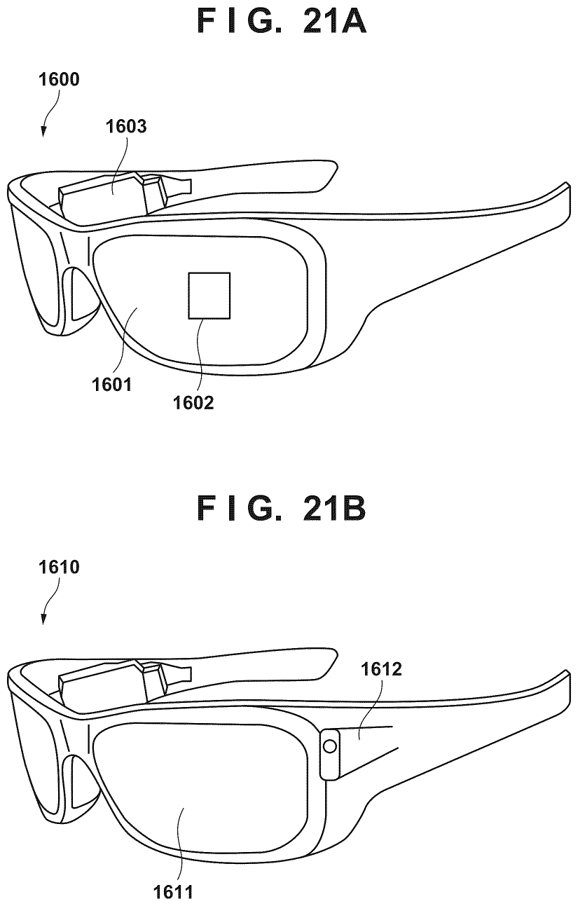

Further application examples of the light emitting device 600 according to this embodiment will be described with reference to FIGS. 21A and 21B. The light emitting device 600 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 21A. An image capturing device 1602 such as a CMOS sensor or an SPAD is provided on the surface side of a lens 1601 of the glasses 1600. In addition, the light emitting device 600 according to this embodiment is provided on the back surface side of the lens 1601.

The glasses 1600 further include a control device 1603. The control device 1603 functions as a power supply that supplies electric power to the image capturing device 1602 and the light emitting device 600 according to each embodiment. In addition, the control device 1603 controls the operations of the image capturing device 1602 and the light emitting device 600. An optical system configured to condense light to the image capturing device 1602 is formed on the lens 1601.

Glasses 1610 (smartglasses) according to one application example will be described with reference to FIG. 21B. The glasses 1610 include a control device 1612, and an image capturing device corresponding to the image capturing device 1602 and the light emitting device 600 are mounted on the control device 1612. The image capturing device in the control device 1612 and an optical system configured to project light emitted from the light emitting device 600 are formed in a lens 1611, and an image is projected to the lens 1611. The control device 1612 functions as a power supply that supplies electric power to the image capturing device and the light emitting device 600, and controls the operations of the image capturing device and the light emitting device 600. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 600 according to the embodiment of the present disclosure can include an image capturing device including a light receiving element, and control a displayed image based on the line-of-sight information of the user from the image capturing device.

More specifically, the light emitting device 600 decides a first visual field region at which the user is gazing and a second visual field region other than the first visual field region based on the line-of-sight information. The first visual field region and the second visual field region may be decided by the control device of the light emitting device 600, or those decided by an external control device may be received. In the display region of the light emitting device 600, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 600, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 600, the image capturing device, or an external device. If the external device holds the AI program, it is transmitted to the light emitting device 600 via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-048568, filed Mar. 25, 2024, which is hereby incorporated by reference herein in its entirety.

What is claimed is:

1. A light emitting device that comprises a light emitting element including a first electrode arranged on a main surface of a substrate, a bank arranged to cover an outer edge of the first electrode and provided with an opening portion configured to expose the first electrode inside the outer edge, an organic layer arranged on the first electrode, and a second electrode arranged to cover the organic layer,
wherein the organic layer includes a light emitting layer and connected to the first electrode in the opening portion,
a side surface of the bank facing the opening portion includes a first surface formed by a first portion made of a first material, and a second surface arranged between the first surface and the first electrode and formed by a second portion made of a second material different from the first material,
the first portion reflects more light emitted by the light emitting layer than the second portion, and
the second portion has insulating property, and absorbs more light emitted by the light emitting layer than the first portion.

2. The device according to claim 1, wherein the bank has a stacked structure of a first layer including the first portion and made of the first material, and a second layer including the second portion and made of the second material.

3. The device according to claim 1, wherein a virtual line passing through a boundary between the first surface and the second surface and parallel to the main surface passes between a lower surface and an upper surface of a portion of the light emitting layer overlapping a center of the first electrode in an orthogonal projection to the main surface.

4. The device according to claim 1, wherein the first surface forms a smaller internal angle with a surface of the first electrode than the second surface.

5. The device according to claim 1, wherein
the first surface has an internal angle smaller than 60° with respect to a surface of the first electrode, and
the second surface has an internal angle of not less than 60° and not more than 90° with respect to the surface.

6. The device according to claim 1, wherein the side surface has an internal angle of not less than 60° and not more than 90° with respect to a surface of the first electrode.

7. The device according to claim 1, wherein an insulating layer covering the bank is further arranged between the bank and the organic layer.

8. The device according to claim 1, wherein
the side surface further includes a third surface formed by a third portion made of a third material different from the first material,
the first surface is arranged between the third surface and the second surface,
the first portion reflects more light emitted by the light emitting layer than the third portion, and
the third portion absorbs more light emitted by the light emitting layer than the first portion.

9. The device according to claim 8, wherein the bank has a stacked structure of a first layer including the first portion and made of the first material, a second layer including the second portion and made of the second material, and a third layer including the third portion and made of the third material.

10. The device according to claim 8, wherein the second material and the third material are the same material.

11. The device according to claim 8, wherein a length of the third surface in a normal direction of the main surface is smaller than a length of the first surface in the normal direction.

12. The device according to claim 1, further including, between the first electrode and the main surface, a reflective layer configured to reflect light emitted by the light emitting layer,
wherein the first electrode transmits light emitted by the light emitting layer.

13. The device according to claim 1, comprising a plurality of light emitting elements including the light emitting element.

14. The device according to claim 12, comprising a plurality of light emitting elements including the light emitting element,
wherein
the plurality of light emitting elements include a first light emitting element and a second light emitting element, and
a length between the first electrode and the reflective layer in the first light emitting element is different from a length between the first electrode and the reflective layer in the second light emitting element.

15. The device according to claim 13, wherein the organic layer is shared by the plurality of light emitting elements.

16. The device according to claim 13, wherein the organic layer is arranged independently for each of the plurality of light emitting elements.

17. The device according to claim 1, wherein the first material includes at least one of aluminum, silver, and platinum.

18. The device according to claim 1, wherein the second material includes at least one of chromium oxide, tantalum nitride, manganese nitride, a resin added with a black pigment, and a resin added with a black dye.

19. A display device comprising the light emitting device according to claim 1, and an active element connected to the light emitting device.

20. A photoelectric conversion device comprising an optical unit including a plurality of lenses, an image sensor configured to receive light having passed through the optical unit, and a display unit configured to display an image,
wherein the display unit displays an image captured by the image sensor, and includes the light emitting device according to claim 1.

21. An electronic apparatus comprising a housing provided with a display unit, and a communication unit provided in the housing and configured to perform external communication,
wherein the display unit includes the light emitting device according to claim 1.
